(19) United States
(12) Patent Application Publication
(10) Pub. No.: US 2006/0096540 A1
(43) Pub. Date: May 11, 2006

(54) Apparatus to manufacture semiconductor

(76) Inventor: Jin Hyuk Choi, Suwon-si (KR)

Correspondence Address: STANZIONE & KIM, LLP, 919 18TH STREET, N.W., SUITE 440, WASHINGTON, DC, 20006, US

(21) Appl. No.: 11/142,246

(22) Filed: Jun. 2, 2005

(30) Foreign Application Priority Data
Nov. 11, 2004 (KR) 2004-91828

(51) Int. Cl. C23C 16/00

(52) U.S. Cl. 118/724

(57) ABSTRACT

An apparatus to manufacture a semiconductor, in which distribution of process gases supplied to a reaction region in a reaction chamber is uniform, includes a gas supply nozzle to supply process gases to a semiconductor substrate in the reaction chamber, wherein the gas supply nozzle includes a first supply channel formed in a longitudinal direction, and first outlet channels formed at an outlet of the first supply channel such that the first outlet channels are inclined with respect to the direction of the first supply channel at a designated angle to diffuse the process gas supplied through the first supply channel.

### CROSS-REFERENCE TO RELATED APPLICATIONS

This application claims the benefit under 35 U.S.C. § 119 of Korean Patent Application No. 2004-91828, filed November 11, 2004, in the Korean Intellectual Property Office, the disclosure of which is incorporated herein in its entirety by reference.

### BACKGROUND OF THE INVENTION

1. Field of the Invention

The present general inventive concept relates to an apparatus to manufacture a semiconductor, and more particularly, to an apparatus to manufacture a semiconductor having an improved gas supply nozzle so that process gases are uniformly sprayed onto a semiconductor substrate.

2. Description of the Related Art

Generally, when a conventional depositing or etching process is performed during manufacturing of a semiconductor, reactive process gas is supplied to the inside of a reaction chamber in a vacuum state, and then high-frequency power is supplied to the inside of the reaction chamber so that the process gas is dissociated into a plasma state and simultaneously chemically reacted, thereby performing a depositing or etching process on a surface of a semiconductor substrate.

During the above process, when the process gas supplied to the inside of the reaction chamber is uniformly distributed around the semiconductor substrate, the process gas is uniformly deposited onto the surface of the semiconductor substrate, thereby producing a film having an excellent quality. Further, during the etching process, when the process gas is uniformly distributed around the semiconductor substrate, a sputtering operation is uniformly performed, thereby producing a desired etching result. Accordingly, gas supply nozzles for uniformly supplying the process gas to a reaction region around the substrate are installed in a conventional apparatus for manufacturing a semiconductor.

U.S. Pat. No. 6,486,081 discloses an installation structure of gas supply nozzles for supplying process gas to an inside of a conventional apparatus for manufacturing a semiconductor. The conventional apparatus, disclosed by the above Patent, comprises a plurality of side gas supply nozzles installed through a side surface of the conventional apparatus for supplying the process gas to the inside of a reaction chamber, and an upper gas supply nozzle installed through a central portion of an upper surface of the conventional apparatus for supplying the process gas to an upper portion of a semiconductor substrate. The side gas supply nozzles include first and second gas supply nozzles respectively connected to first and second gas supply sources for supplying first and second process gases to the inside of the reaction chamber, and the upper gas supply nozzle includes third and fourth gas supply channels respectively connected to third and fourth gas supply sources for supplying third and fourth process gases to the inside of the reaction chamber.

Since the above apparatus is configured such that an outlet of the upper gas supply nozzle has a rectilinear shape, it is difficult to uniformly distribute the process gas onto an upper surface of a substrate due to a concentration of the process gas supplied through the upper gas nozzle onto a central portion of the semiconductor substrate. Accordingly, it is difficult to obtain a film uniformly formed on the overall surface of the semiconductor substrate, i.e., the film can be concentrated onto the central portion of the semiconductor substrate instead of uniformly formed over all of the surface of the substrate.

### SUMMARY OF THE INVENTION

Accordingly, the present general inventive concept provides an apparatus to manufacture a semiconductor, which increases a diffusion range of process gases supplied from gas supply nozzles so that the process gases are uniformly distributed onto a reaction region above a semiconductor substrate, thereby uniformly performing a desired processing procedure.

Additional aspects and advantages of the present general inventive concept will be set forth in part in the description which follows and, in part, will be obvious from the description, or may be learned by practice of the general inventive concept.

The foregoing and/or other aspects and advantages of the present general inventive concept are achieved by providing an apparatus to manufacture a semiconductor including a gas supply nozzle to supply process gases to a semiconductor substrate in a reaction chamber, wherein the gas supply nozzle includes a first supply channel formed in a longitudinal direction, and first outlet channels formed at an outlet of the first supply channel such that the first outlet channels are inclined with respect to the direction of the first supply channel at a designated angle to diffuse the process gas supplied through the first supply channel.

The gas supply nozzle may further include second supply channels formed in a longitudinal direction separately from the first supply channel, and second outlet channels formed at outlets of the second supply channels such that the second outlet channels are inclined with respect to the direction of the first and second supply channels at a designated angle to diffuse the process gas supplied through the second supply channels.

The first supply channel may be disposed at a central portion of the gas supply nozzle, and the second supply channels may be disposed in a plural number outside the first supply channel such that the second supply channels are symmetric with respect to a central axis of the gas supply nozzle.

The gas supply nozzle may be installed at an upper portion of the reaction chamber coinciding with a position of a central axis of a semiconductor substrate, and the direction of the first supply channel may coincide with the direction of the central axis of the semiconductor substrate.

The first outlet channels and the second outlet channels may be prepared in a plural number such that the first outlet channels and the second outlet channels are symmetric with respect to the central axis of the gas supply nozzle.

At least one of the first and second supply channels may supply a plurality of process gases in a mixed state, and the plurality of process gases in the mixed state may include reactive process gas and non-reactive process gas.

The reactive process gas may be supplied by one of the first and second supply channels, and the non-reactive process gas may be supplied by the other one of the first and second supply channels.

### BRIEF DESCRIPTION OF THE DRAWINGS

These and/or other aspects and advantages of the general inventive concept will become apparent and more readily appreciated from the following description of the embodiments, taken in conjunction with the accompanying drawings in which:

FIG. 1 is a longitudinal sectional view of an apparatus to manufacture a semiconductor according to an embodiment of the present general inventive concept; and

FIG. 2 is a longitudinal sectional view of an upper gas supply nozzle of the apparatus of FIG. 1.

### DETAILED DESCRIPTION OF THE PREFERRED EMBODIMENTS

Reference will now be made in detail to the embodiment of the present general inventive concept, an example of which is illustrated in the accompanying drawings, wherein like reference numerals refer to like elements throughout. The embodiment is described below to explain the present general inventive concept while referring to the drawings.

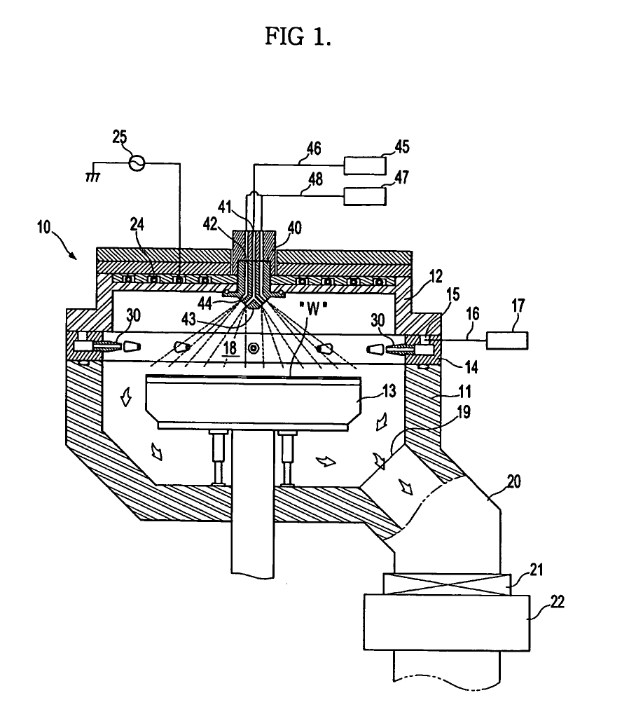

FIG. 1 is a longitudinal sectional view of an apparatus 10 to manufacture a semiconductor according to an embodiment of the present general inventive concept. Referring to FIG. 1, the apparatus 10 comprises a reaction chamber 18 to perform a fabricating process of a semiconductor substrate W therein, including a cylindrical main body 11 having an opened upper surface and a cover 12 to cover the opened upper surface of the main body 11. Here, the fabricating process performed by the apparatus 10 is either a depositing process to form a thin film on a surface of the semiconductor substrate W, or an etching process to etch the film on the surface of the semiconductor substrate W to form a designated pattern.

A chuck 13 to support the semiconductor substrate W is installed in the reaction chamber 18. The chuck 13 is an electrostatic chuck to fix the semiconductor substrate W using an electrostatic force. A plurality of gas supply nozzles, including side gas supply nozzles 30 and an upper gas supply nozzle 40 to supply process gases to an inside of the reaction chamber 18 so that the depositing or etching process is performed in the reaction chamber 18. The side gas supply nozzles 30 and the upper gas supply nozzle 40 are installed at a lower end of the cover 12 and a central position of an upper portion of the cover 12, respectively.

An outlet 19 to discharge a reaction byproduct and non-reacted process gas externally from the reaction chamber 18 is formed through a lower portion of the main body 11. A vacuum pump 22 to maintain a vacuum inside of the reaction chamber 13 and a pressure control unit 21 are installed in a discharge pipe 20 connected to the outlet 19.

An induction coil 24 to generate an electric field, which excites the process gases supplied to the inside of the reaction chamber 18 into a plasma state, is installed on an upper surface of the cover 12, and a high frequency power source 25 is connected to the induction coil 24. The cover 12 can be made of ceramic so that the electric field generated by the induction coil 24 is contained inside the cover 12 to excite the process gases in the reaction chamber 18 into the plasma state. Bias power is applied to the chuck 13 in the reaction chamber 18 so that the process gases in the plasma state are induced to the semiconductor substrate W.

When the depositing process is performed using the above apparatus 10, the semiconductor substrate W is fixed to the chuck 13 in the reaction chamber 18, and the process gases to perform the depositing process are supplied to the inside of the reaction chamber 18 through the side gas supply nozzles 30 and the upper gas supply nozzle 40. The inside of the reaction chamber 18 is maintained in a vacuum state by the vacuum pump 22 and the pressure control device 21, and power is applied to the induction coil 24 so that the process gases in the reaction chamber 18 are excited into the plasma state. Accordingly, the process gases dissociate and chemically react, thereby forming a thin film on the surface of the semiconductor surface W by deposition.

When the etching process on the surface of the semiconductor substrate W is performed, the process gases to perform the etching process are supplied to the reaction chamber 18 through the side gas supply nozzles 30 and the upper gas supply nozzle 40, and converted into the plasma state. Then, ionized particles of the gases physically collide with the semiconductor substrate W and chemically react, thereby etching the thin film formed on the semiconductor substrate W.

In the depositing or etching process as described above, when the process gases are uniformly distributed around the semiconductor substrate W and have a high density, the desired process is uniformly performed. In order to uniformly supply the process gases to a reaction region on an upper surface of the semiconductor substrate W, the apparatus 10 comprises a plurality of the side gas supply nozzles 30 formed through a side surface of the reaction chamber 18, and the upper gas supply nozzle 40 formed through the central position of the upper portion of the cover 12.

The side gas supply nozzles 30 are installed in a circular gas distribution ring 14 connected to the lower end of the cover 12 such that the side gas supply nozzles 30 are spaced apart from each other by the same interval. A gas guide groove 15 to supply the process gas to the side gas supply nozzles 30 is formed in the gas distribution ring 14 and is connected to a first gas supply unit 17 to supply a first process gas through a pipe 16. The gas guide groove 15 serves to supply the first process gas supplied from the first gas supply unit 17 to the inside of the reaction chamber 18 through the side gas supply nozzles 30.

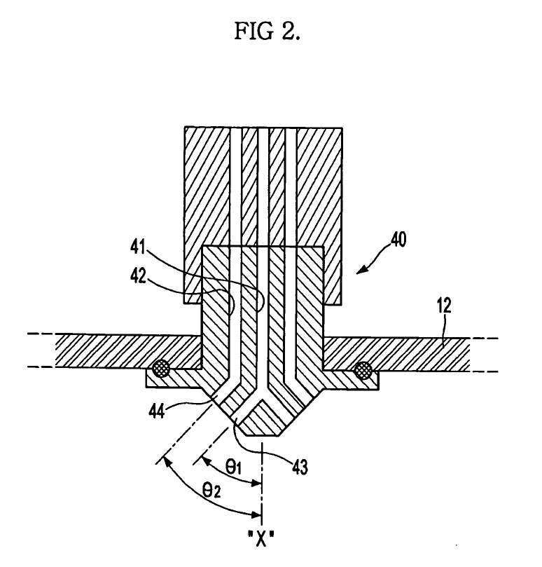

FIG. 2 is a longitudinal sectional view of the upper gas supply nozzle 40 of the apparatus 10. Referring to FIGS. 1 and 2, the upper gas supply nozzle 40 includes a first supply channel 41 vertically formed through a central portion thereof, and a plurality of second supply channels 42 vertically formed separately from the first supply channel 41 and in parallel with the first supply channel 41. Here, the direction of the first supply channel 41 coincides with the direction of a central axis (X) of the semiconductor substrate W. The plurality of second supply channels 42 may be formed adjacent to the first supply channel 41.

A plurality of first outlet channels 43, which are inclined with respect to the direction of the first supply channel 41 at a designated angle (θ₁) and are symmetric with respect to the central axis (X), are formed at an outlet of the first supply channel 41. A plurality of second outlet channels 44, which are inclined with respect to the direction of the first and second supply channels 41 and 42 at a designated angle (θ₂) and are symmetric with respect to the central axis (X), are formed at outlets of the second supply channels 42. The angle (θ₁) of inclination of the first outlet channels 43 may be the same as the angle (θ₂) of inclination of the second outlet channels 44. However, the angle (θ₁) of inclination of the first outlet channels 43 and the angle (θ₂) of inclination of the second outlet channels 44 may be set to different values according to a size of the semiconductor substrate or conditions of the fabricating process.

The above described configuration allows the process gases, which are supplied through the first and second supply channels 41 and 42, to be uniformly diffused onto the upper surface of a semiconductor substrate (W) in the reaction chamber 18 through the inclined first and second outlet channels 43 and 44, thereby uniformly distributing the process gases on the upper surface of the substrate (W) so that the fabricating process (depositing or etching process) of the substrate (W) is uniformly performed.

As illustrated in FIG. 1, a second gas supply unit 45 to supply a second process gas is connected to the first supply channel 41 of the upper gas supply nozzle 40 by a pipe 46, and a third gas supply unit 47 to supply a third process gas is connected to the second supply channels 42 by a pipe 48. The above configuration serves to supply separate process gases respectively to the first supply channel 41 and the second supply channels 42. Here, although not shown in detail, the first gas supply unit 17, the second gas supply unit 45, and the third gas supply unit 47 may be storage containers to store the process gases or gas generators to generate the process gases, and may respectively include valve systems to control the supply of the process gases.

Among the process gases supplied to the inside of the reaction chamber 18, the first process gas supplied through the side gas supply nozzles 30 may be a reactive gas, such as silane (SiH₄), and the second process gas supplied through the first supply channel 41 of the upper gas supply nozzle 40 may be a reactive gas, such as oxygen (O₂). Further, the third process gas supplied through the second supply channels 42 of the upper gas supply nozzle 40 may be a non-reactive gas, such as helium (He) or argon (Ar).

Alternatively, the reactive gas, such as silane (SiH₄), may be supplied through the first supply channel 41 of the upper gas supply nozzle 40, and the reactive gas, such as oxygen (O₂), and the non-reactive gas, such as helium (He) or argon (Ar), may be supplied in a mixed state through the second supply channels 42 of the upper gas supply nozzle 40.

As described above, the simultaneous supply of the reactive gas and the non-reactive gas through the upper gas supply nozzle 40 causes the reactive gas, such as oxygen (O₂), to be pushed by the non-reactive gas, such as helium (He) or argon (Ar), and to be uniformly distributed onto a region above the semiconductor substrate (W). That is, a supply direction of the reactive gas can be controlled by the supply of the non-reactive gas. This induces the uniform distribution of the reactive gas, thereby forming a uniform film on the surface of the semiconductor substrate (W).

As apparent from the above description, the present general inventive concept provides an apparatus to manufacture a semiconductor, in which a plurality of process gases are simultaneously supplied through an upper gas supply nozzle, and the process gases supplied through the upper gas supply nozzle are diffused through inclined first and second outlet channels, so that the process gases are uniformly distributed on an upper surface of a semiconductor substrate, thereby uniformly performing a depositing or etching process.

Although an embodiment of the general inventive concept has been shown and described, it would be appreciated by those skilled in the art that changes may be made in this embodiment without departing from the principles and spirit of the general inventive concept, the scope of which is defined in the claims and their equivalents.

What is claimed is:

1. An apparatus to manufacture a semiconductor comprising a gas supply nozzle to supply process gases to a semiconductor substrate in a reaction chamber, the gas supply nozzle comprising:
a first supply channel formed in a longitudinal direction; and
first outlet channels formed at an outlet of the first supply channel such that the first outlet channels are inclined with respect to the direction of the first supply channel at a designated angle to diffuse the process gas supplied through the first supply channel.

2. The apparatus as set forth in claim 1, wherein the gas supply nozzle further includes second supply channels formed in a longitudinal direction separately from the first supply channel, and second outlet channels formed at outlets of the second supply channels such that the second outlet channels are inclined with respect to the direction of the first and second supply channels at a designated angle to diffuse the process gas supplied through the second supply channels.

3. The apparatus as set forth in claim 2, wherein the first supply channel is disposed at a central portion of the gas supply nozzle, and the second supply channels are disposed in a plural number outside the first supply channel such that the second supply channels are symmetric with respect to a central axis of the gas supply nozzle.

4. The apparatus as set forth in claim 3, wherein the gas supply nozzle is installed at an upper portion of the reaction chamber coinciding with a central axis of the semiconductor substrate, and the direction of the first supply channel coincides with the direction of the central axis of the semiconductor substrate.

5. The apparatus as set forth in claim 3, wherein the first outlet channels and the second outlet channels are provided in a plural number such that the first outlet channels and the second outlet channels are symmetric with respect to the central axis of the gas supply nozzle.

6. The apparatus as set forth in claim 2, wherein at least one of the first and second supply channels supplies a plurality of the process gases in a mixed state.

7. The apparatus as set forth in claim 6, wherein a plurality of the process gases in the mixed state include reactive process gas and non-reactive process gas.

8. The apparatus as set forth in claim 2,
wherein reactive process gas is supplied by one of the first and second supply channels, and non-reactive process gas is supplied by the other one of the first and second supply channels.

9. An apparatus to manufacture a semiconductor, comprising:
a reaction chamber; and
a gas supply nozzle provided at an upper portion of the reaction chamber and comprising a gas supply channel having angled outlets communicating with the reaction chamber to supply process gas to the reaction chamber at a first predetermined angle with respect to the gas supply channel.

10. The apparatus as set forth in claim 9, wherein the upper gas supply nozzle further comprises:
a plurality of outer gas supply channels in parallel with the gas supply channel and formed symmetrically on opposite sides of the gas supply channel, each outer gas supply channel having an angled outlet communicating with the reaction chamber to supply a second process gas at a second predetermined angle with respect to the respective outer gas supply channel.

11. The apparatus as set forth in claim 10, wherein the second predetermined angle is the same as the first predetermined angle.

12. The apparatus as set forth in claim 9, wherein the angled outlets are symmetrically angled away from the gas supply channel in opposite directions.

13. An apparatus to manufacture a semiconductor, comprising:
a reaction chamber; and
a gas supply nozzle provided at an upper portion of the reaction chamber and formed with a first supply channel to supply a first process gas to the reaction chamber, the first supply channel including an upper portion vertically formed through the center of the gas supply nozzle and a lower portion extending from the upper portion in two symmetrically angled opposing directions to deposit the first process gas into the reaction chamber.

14. The apparatus as set forth in claim 13, wherein the gas supply nozzle is further formed with a plurality of second supply channels symmetrically disposed on opposite sides of the first supply channel to supply a second process gas to the reaction chamber, each second supply channel including an upper portion formed in parallel with the upper portion of the first supply channel and a lower portion extending away from the upper portion and the first supply channel to deposit the second process gas in the direction extending away from the upper portion such that the second process gas is evenly distributed within the reaction chamber.

15. The apparatus as set forth in claim 14, wherein the lower portion of each of the plurality of second supply channels is parallel to one of two branches of the lower portion of the first supply channel.

16. An apparatus to manufacture a semiconductor, comprising:
a reaction chamber; and
a gas supply nozzle including a plurality of angled gas supply outlets angled away from an upper center portion of the reaction chamber to transfer process gas into the reaction chamber.

17. The apparatus as set forth in claim 16, wherein the plurality of angled gas supply outlets comprises:
a plurality of first gas supply outlets to transfer a reactive process gas into the reaction chamber; and
a plurality of second gas supply outlets to transfer a non-reactive process gas into the reaction chamber.

18. The apparatus as set forth in claim 16, wherein the gas supply nozzle further includes a plurality of gas supply channels, each of the gas supply channels supplying the process gas to a respective one of the angled gas supply outlets.

19. The apparatus as set forth in claim 16, wherein the plurality of angled gas supply outlets are angled at a predetermined angle to cause the process gas transferred into the reaction chamber to diffuse evenly throughout the reaction chamber.

20. An apparatus to manufacture a semiconductor, comprising:
a main body forming a reaction chamber to perform a semiconductor fabrication process;
a plurality of side gas supply nozzles formed through a side portion of the main body to supply a first process gas to the reaction chamber;
an upper gas supply nozzle comprising a central channel to supply a second process gas to the reaction chamber through two angled outlet channels communicating with the central channel and the reaction chamber and a plurality of outer channels symmetrically provided on opposite sides of the central channel to supply a third process gas to the reaction chamber through a respective plurality of outer angled outlet channels each communicating with the respective outer channel and the reaction chamber.
